(19) United States
(12) Patent Application Publication
(10) Pub. No.: US 2025/0318247 A1
(43) Pub. Date: Oct. 9, 2025

(54) p-GaN SEMICONDUCTOR DEVICE AND METHOD FOR FABRICATING THE SAME

(71) Applicant: National Yang Ming Chiao Tung University, Hsinchu City (TW)

(72) Inventors: Tian-Li WU, Taoyuan City (TW); Hung-Chun CHEN, New Taipei City (TW); Tzu-Heng LIN, Taoyuan City (TW)

(73) Assignee: National Yang Ming Chiao Tung University, Hsinchu City (TW)

(21) Appl. No.: 18/773,861

(22) Filed: Jul. 16, 2024

(30) Foreign Application Priority Data
Apr. 9, 2024 (TW) 113113099

(51) Int. Cl. H01L 27/06; H01L 21/8252; H01L 29/20; H01L 29/66; H01L 29/778; H01L 29/872

(52) U.S. Cl. CPC H10D 84/01; H10D 8/051; H10D 8/60; H10D 30/015; H10D 30/475; H10D 62/8503; H10D 84/05; H10D 84/811

(57) ABSTRACT

The disclosure describes a p-GaN semiconductor device and a method for fabricating the same. The p-GaN semiconductor device includes a substrate, a nucleation layer, a buffer layer, a GaN layer, an AlGaN layer, at least one cathode, a p-GaN termination structure, and an anode. The nucleation layer, the buffer layer, the GaN layer, and the AlGaN layer are sequentially formed on the substrate. The cathode penetrates through the AlGaN layer and directly interfaces the GaN layer. The p-GaN termination structure is penetrated with a hole and formed on the AlGaN layer. The anode, formed on the p-GaN termination structure and the AlGaN layer, fills the hole.

### BACKGROUND OF THE INVENTION

This application claims priority for the TW Application No. 113113099 filed on 9 Apr. 2024, the content of which is incorporated by reference in its entirely.

### FIELD OF THE INVENTION

The present invention relates to technology for fabricating semiconductor, particularly to a p-GaN semiconductor device and a method for fabricating the same.

### DESCRIPTION OF THE RELATED ART

As one of the representative wide energy gap materials, gallium nitride has the advantages of wider energy gap, higher saturation current and higher breakdown electric field compared with traditional silicon materials. The existing technology uses recessed gallium nitride metal-insulator-semiconductor high electron mobility transistors (recessed GaN MISHEMTs) and P-type gallium nitride high electron mobility transistors (p-GaN HEMTs) to meet the normally-off operation in the market or the requirements of enhancement-mode devices.

Gallium nitride components are discrete components that cannot be integrated into integrated circuits on wafers. Gallium nitride components must be packaged with silicon components to meet market demand for enhanced components. However, circuit packaging creates additional fabrication costs. For example, when the GaN diode is implemented with a gated edge termination structure, the integration of the GaN diode with the P-type GaN transistor will cause complex epitaxy problems. The winding used in circuit packaging will produce parasitic resistance and parasitic capacitance, which will limit the performance of the circuit and reduce the reliability of the circuit.

To overcome the abovementioned problems, the present invention provides a p-GaN semiconductor device and a method for fabricating the same, so as to solve the afore-mentioned problems of the prior art.

### SUMMARY OF THE INVENTION

The present invention provides a p-GaN semiconductor device and a method for fabricating the same, which reduce the cost and the instability of fabrication processes.

In an embodiment of the present invention, a p-GaN semiconductor device includes a substrate, a nucleation layer, a buffer layer, a GaN layer, an AlGaN layer, at least one cathode, a p-GaN termination structure, and an anode. The nucleation layer is formed on the substrate. The buffer layer is formed on the nucleation layer. The GaN layer is formed on the buffer layer. The AlGaN layer is formed on the GaN layer. The cathode penetrates through the AlGaN layer and directly interfaces the GaN layer. The p-GaN termination structure is penetrated with a hole and formed on the AlGaN layer. The anode, formed on the p-GaN termination structure and the AlGaN layer, fills the hole.

In an embodiment of the present invention, the p-GaN semiconductor device further includes a source, a drain, a p-GaN structure and a gate. The source and the drain separate from each other, penetrate through the AlGaN layer, and directly interface the GaN layer. The p-GaN structure is formed on the AlGaN layer between the source and the drain. The gate is formed on the p-GaN structure.

In an embodiment of the present invention, the p-GaN semiconductor device further includes an isolation structure formed in the AlGaN layer and the GaN layer. The isolation structure has a first side and a second side opposite to the first side. The cathode is formed on the first side of the isolation structure. The source and the drain are formed on the second side of the isolation structure.

In an embodiment of the present invention, the isolation structure surrounds the at least one cathode, the source, and the drain.

In an embodiment of the present invention, the p-GaN semiconductor device further includes an insulation layer that covers the isolation structure, the AlGaN layer, the p-GaN termination structure, the p-GaN structure, a part of the cathode, a part of the anode, a part of the source, and a part of the drain.

In an embodiment of the present invention, the p-GaN semiconductor device further includes an etch stopping layer formed between the AlGaN layer and the p-GaN termination structure and formed between the AlGaN layer and the p-GaN structure.

In an embodiment of the present invention, the etch stopping layer comprises AlN.

In an embodiment of the present invention, the buffer layer comprises GaN or AlGaN.

In an embodiment of the present invention, the nucleation layer comprises AlN.

In an embodiment of the present invention, the substrate is a Si substrate, a SiC substrate, a sapphire substrate, or a GaN substrate.

In an embodiment of the present invention, a method for fabricating a p-GaN semiconductor device includes: sequentially forming a nucleation layer, a buffer layer, a GaN layer, an AlGaN layer, and a p-GaN structural layer on a substrate; removing a part of the p-GaN structural layer to form a p-GaN termination structure penetrated with a hole on the AlGaN layer; forming an anode on the p-GaN termination structure and the AlGaN layer to fill the hole; and removing a part of the AlGaN layer to expose at least one first block of the GaN layer and forming at least one cathode on the at least one first block of the GaN layer, wherein the at least one cathode directly interfaces the at least one first block of the GaN layer.

In an embodiment of the present invention, after the step of forming the p-GaN structural layer, an isolation structure is formed in the AlGaN layer and the GaN layer and then the part of the p-GaN structural layer and the part of the AlGaN layer are removed. The isolation structure has a first side and a second side opposite to the first side. The cathode and the first block are formed on the first side.

In an embodiment of the present invention, a part of the p-GaN structural layer is removed to form the p-GaN termination structure on the AlGaN layer on the first side and form a p-GaN structure on the AlGaN layer on the second side. A part of the AlGaN layer is removed to expose the first block, the second block, and the third block of the GaN layer and the cathode, a source, and a drain are respectively formed on the first block, the second block, and the third block. The first block and the cathode are formed on the first side. The source, the drain, the second block, and the third block are formed on the second side, and the source and the drain, respectively formed on two opposite sides of the AlGaN layer under the p-GaN structure, respectively directly interface the second block and the third block. The anode is formed on the p-GaN termination structure and the AlGaN layer and a gate is formed on the p-GaN structure.

In an embodiment of the present invention, the isolation structure surrounds the cathode, the source, and the drain.

In an embodiment of the present invention, the method for fabricating the p-GaN semiconductor device further includes a step of forming an insulation layer to cover the isolation structure, the AlGaN layer, the p-GaN termination structure, the p-GaN structure, a part of the cathode, a part of the anode, a part of the source, and a part of the drain.

In an embodiment of the present invention, the nucleation layer, the buffer layer, the GaN layer, the AlGaN layer, an etch stopping layer, and the p-GaN structural layer are sequentially formed on the substrate.

In an embodiment of the present invention, after the step of forming the p-GaN termination structure and the p-GaN structure, the etch stopping layer exposed by the p-GaN termination structure and the p-GaN structure and then the anode and the gate are formed and a part of the AlGaN layer is removed to expose the first block, the second block, and the third block.

In an embodiment of the present invention, the isolation structure is formed using ion implantation.

To sum up, the p-GaN semiconductor device and the method for fabricating the same replace the dielectric layer with the p-GaN structural layer and etch the p-GaN structural layer under the anode to form the p-GaN termination structure of a Schottky diode, thereby providing holes and improving the stability of the diode. Since the p-GaN termination structure and the GaN structure of the high electron mobility transistor belong to the same epitaxial material, the cost and instability of the fabrication processes can be reduced when the Schottky diode is integrated with the p-GaN transistor. The Schottky diodes and the p-GaN transistors can also be integrated into integrated circuits.

Below, the embodiments are described in detail in cooperation with the drawings to make easily understood the technical contents, characteristics and accomplishments of the present invention.

### BRIEF DESCRIPTION OF THE DRAWINGS

FIG. 1 is a cross-sectional view of a p-GaN semiconductor device according to a first embodiment of the present invention;

FIGS. 2a-2f are schematic diagrams illustrating the steps for fabricating a p-GaN semiconductor device according to the first embodiment of the present invention;

FIG. 3 is a cross-sectional view of a p-GaN semiconductor device according to a second embodiment of the present invention;

FIGS. 4a-4g are schematic diagrams illustrating the steps for fabricating a p-GaN semiconductor device according to the second embodiment of the present invention;

FIG. 5 is a cross-sectional view of a p-GaN semiconductor device according to a third embodiment of the present invention;

FIGS. 6a-6g are schematic diagrams illustrating the steps for fabricating a p-GaN semiconductor device according to the third embodiment of the present invention;

FIG. 7 is a cross-sectional view of a p-GaN semiconductor device according to a fourth embodiment of the present invention; and

FIGS. 8a-8h are schematic diagrams illustrating the steps for fabricating a p-GaN semiconductor device according to the fourth embodiment of the present invention.

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

When an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the articles “a” and “the” includes the meaning of “one or at least one” of the elements or components. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. The examples in the present specification do not limit the claimed scope of the invention.

Furthermore, it can be understood that the terms “comprising,” “including,” “having,” “containing,” and “involving” are open-ended terms, which refer to “may include but is not limited to so.” In addition, each of the embodiments or claims of the present invention is not necessary to achieve all the effects and advantages possibly to be generated, and the abstract and title of the present invention is used to assist for patent search and is not used to further limit the claimed scope of the present invention.

Further, in the present specification and claims, the term “comprising” is open type and should not be viewed as the term “consisted of.” In addition, the term “electrically coupled” can be referring to either directly connecting or indirectly connecting between elements. Thus, if it is described in the below contents of the present invention that a first device is electrically coupled to a second device, the first device can be directly connected to the second device, or indirectly connected to the second device through other devices or means. Moreover, when the transmissions or generations of electrical signals are mentioned, one skilled in the art should understand some degradations or undesirable transformations could be generated during the operations. If it is not specified in the specification, an electrical signal at the transmitting end should be viewed as substantially the same signal as that at the receiving end. For example, when the end A of an electrical circuit provides an electrical signal S to the end B of the electrical circuit, the voltage of the electrical signal S may drop due to passing through the source and drain of a transistor or due to some parasitic capacitance. However, the transistor is not deliberately used to generate the effect of degrading the signal to achieve some result, that is, the signal S at the end A should be viewed as substantially the same as that at the end B.

Unless otherwise specified, some conditional sentences or words, such as “can”, “could”, “might”, or “may”, usually attempt to express what the embodiment in the present invention has, but it can also be interpreted as a feature, element, or step that may not be needed. In other embodiments, these features, elements, or steps may not be required.

In the following description, a p-GaN semiconductor device and a method for fabricating the same will be provided, which replace the dielectric layer with a p-GaN structural layer and etch the p-GaN structural layer under an anode to form the p-GaN termination structure of a Schottky diode, thereby providing holes and improving the stability of the diode. Since a p-GaN termination structure and the GaN structure of the high electron mobility transistor belong to the same epitaxial material, the cost and instability of the fabrication processes can be reduced when the Schottky diode is integrated with the p-GaN transistor. The Schottky diodes and the p-GaN transistors can also be integrated into integrated circuits.

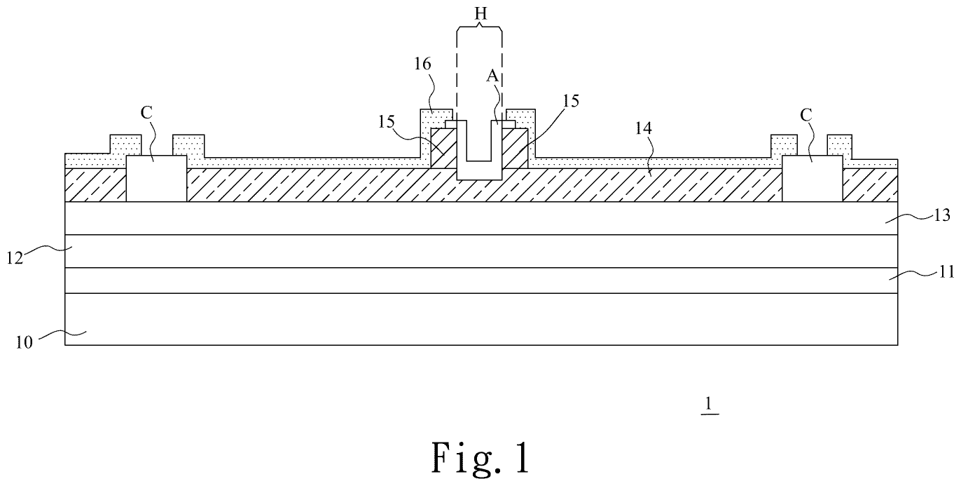

FIG. 1 is a cross-sectional view of a p-GaN semiconductor device according to a first embodiment of the present invention. Referring to FIG. 1, the first embodiment of a p-GaN semiconductor device as the Schottky diode of a p-GaN anode edge termination is introduced as follows. The p-GaN semiconductor device 1 includes a substrate 10, a nucleation layer 11, a buffer layer 12, a GaN layer 13 as a channel layer, an AlGaN layer 14 as a barrier layer, at least one cathode C, a p-GaN termination structure 15, and an anode A. The buffer layer 12 includes, but is not limited to, GaN or AlGaN. The nucleation layer 11 includes, but is not limited to, AlN. The substrate 10 may be, but not limited to, a Si substrate, a SiC substrate, a sapphire substrate, or a GaN substrate. The nucleation layer 11 is formed on the substrate 10. The buffer layer 12 is formed on the nucleation layer 11. The GaN layer 13 is formed on the buffer layer 12. The AlGaN layer 14 is formed on the GaN layer 13. For convenience and clarity, the number of the cathodes C is two. The cathode C penetrates through the AlGaN layer 14 and directly interfaces the GaN layer 13. The p-GaN termination structure 15 is penetrated with a hole H. The p-GaN termination structure 15 is formed on the AlGaN layer 14. The anode A, formed on the p-GaN termination structure 15 and the AlGaN layer 14, fills the hole H. The anode A and the AlGaN layer 14, form a Schottky contact. In some embodiments of the present invention, the p-GaN semiconductor device 1 may further include an insulation layer 16 that covers the AlGaN layer 14, the p-GaN termination structure 15, a part of the cathode C, and a part of the anode A. When a high voltage is applied to the anode A and a low voltage is applied to the cathode, electrons exist at the interface between the GaN layer 13 and the AlGaN layer 14. The p-GaN termination structure 15 can provide holes to neutralize the electrons to improve the stability of the Schottky diode.

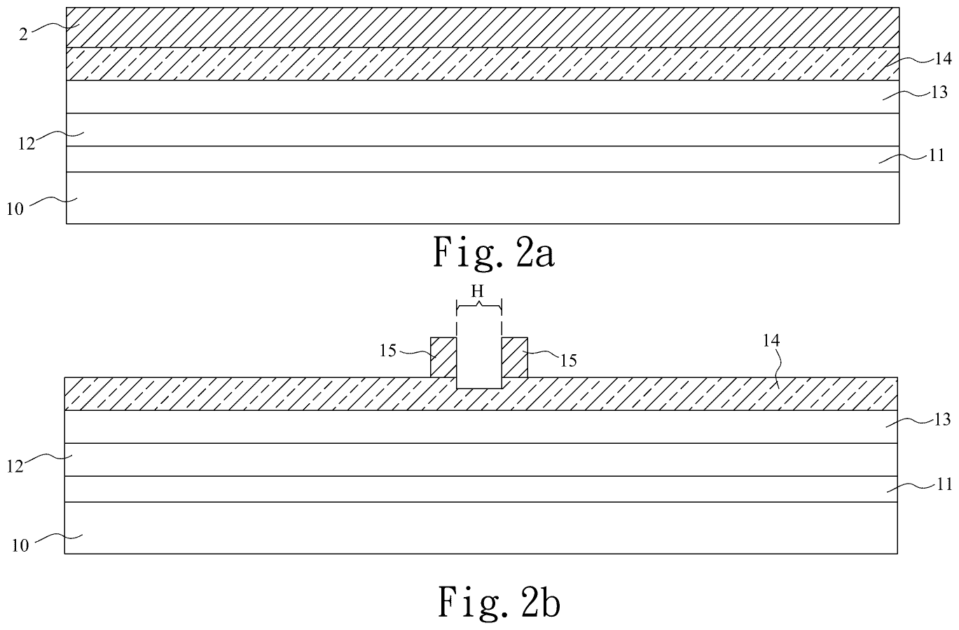

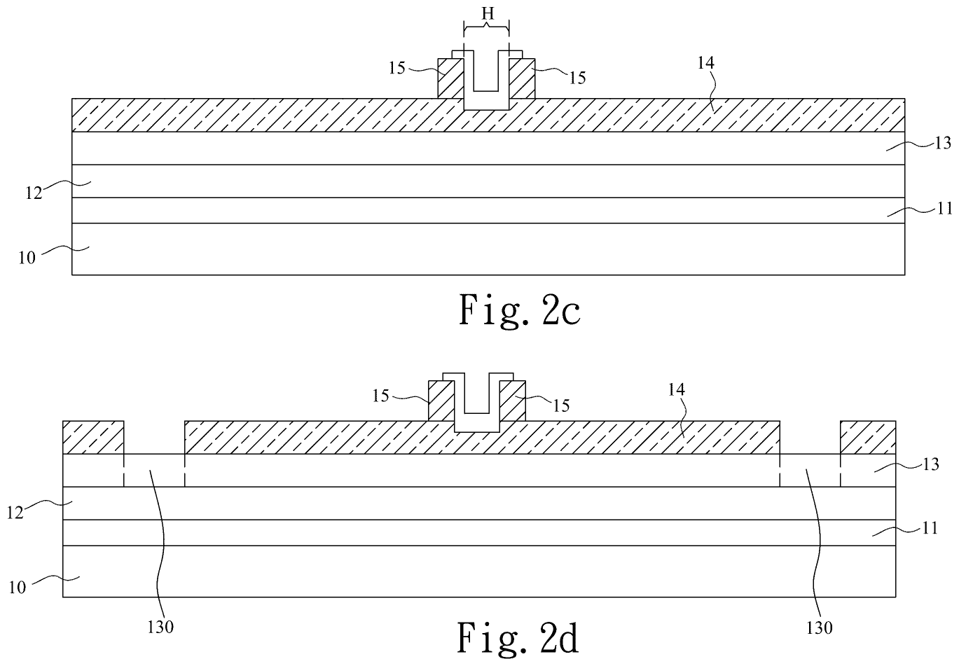

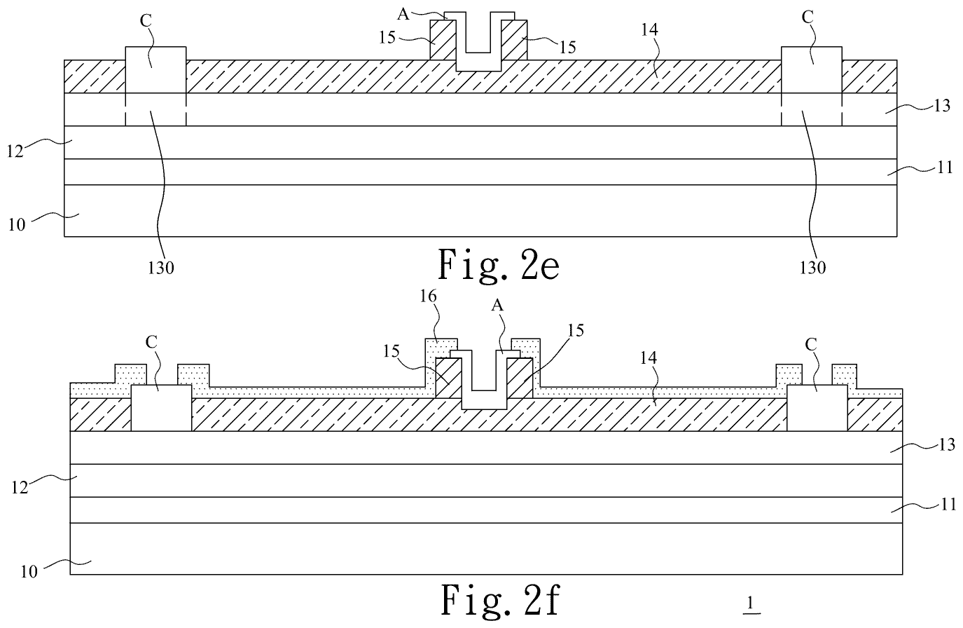

FIGS. 2a-2f are schematic diagrams illustrating the steps for fabricating a p-GaN semiconductor device according to the first embodiment of the present invention. As illustrated in FIG. 2a, a nucleation layer 11, a buffer layer 12, a GaN layer 13, an AlGaN layer 14, and a p-GaN structural layer 2 are sequentially formed on a substrate 10. Then, as illustrated in FIGS. 2a-2b, a part of the p-GaN structural layer 2 is removed to form a p-GaN termination structure 15 penetrated with a hole H on the AlGaN layer 14. As illustrated in FIG. 2c, an anode A is formed on the p-GaN termination structure 15 and the AlGaN layer 14 to fill the hole H. As illustrated in FIGS. 2d-2e, a part of the AlGaN layer 14 is removed to expose at least one first block 130 of the GaN layer 13 and at least one cathode C is formed on the first block 130 of the GaN layer 13. The cathode C directly interfaces the first block 130 of the GaN layer 13. In the embodiment, the number of the first blocks 130 is two and the number of the cathodes C is two. In some embodiments, as illustrated in FIG. 2f, an insulation layer 16 is formed to cover the AlGaN layer 14, the p-GaN termination structure 15, a part of the cathode C, a part of the anode A. Provided that substantially the same result is achieved, the steps of the flowchart shown in FIGS. 2a-2f need not be in the exact order shown and need not be contiguous, that is, other steps can be intermediate.

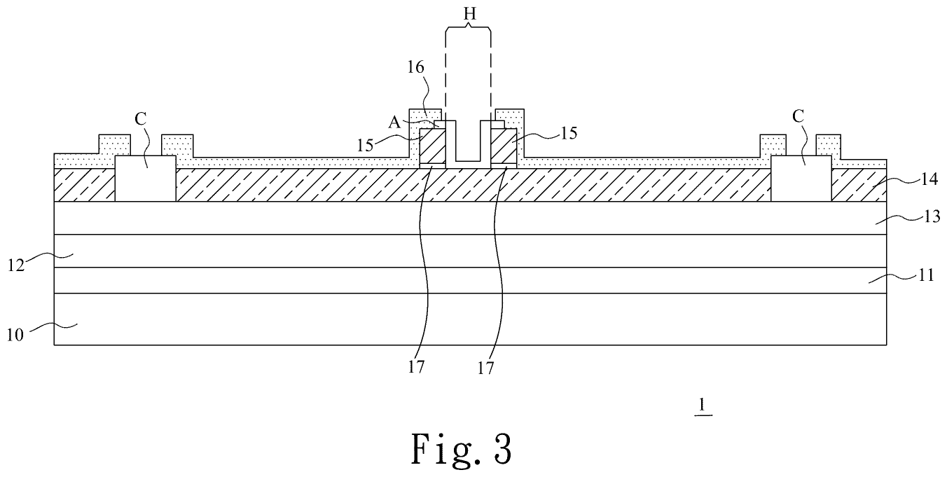

FIG. 3 is a cross-sectional view of a p-GaN semiconductor device according to a second embodiment of the present invention. Referring to FIG. 3, the second embodiment of a p-GaN semiconductor device as the Schottky diode of a p-GaN anode edge termination is introduced as follows. The second embodiment is different from the first embodiment in that the second embodiment further includes an etch stopping layer 17 formed between the AlGaN layer 14 and the p-GaN termination structure 15. The etch stopping layer 17 includes, but is not limited to, AlN. The etch stopping layer 17 is used to avoid over-etching the AlGaN layer 14 and generating many defects. The other structures of the second embodiment have been described in the first embodiment so it will not be reiterated.

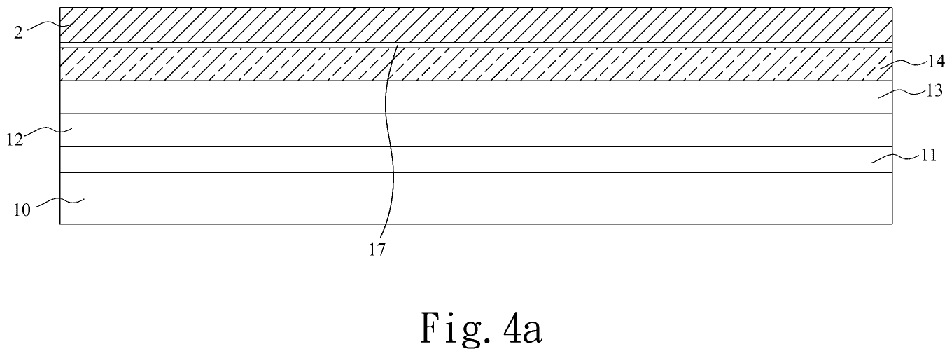

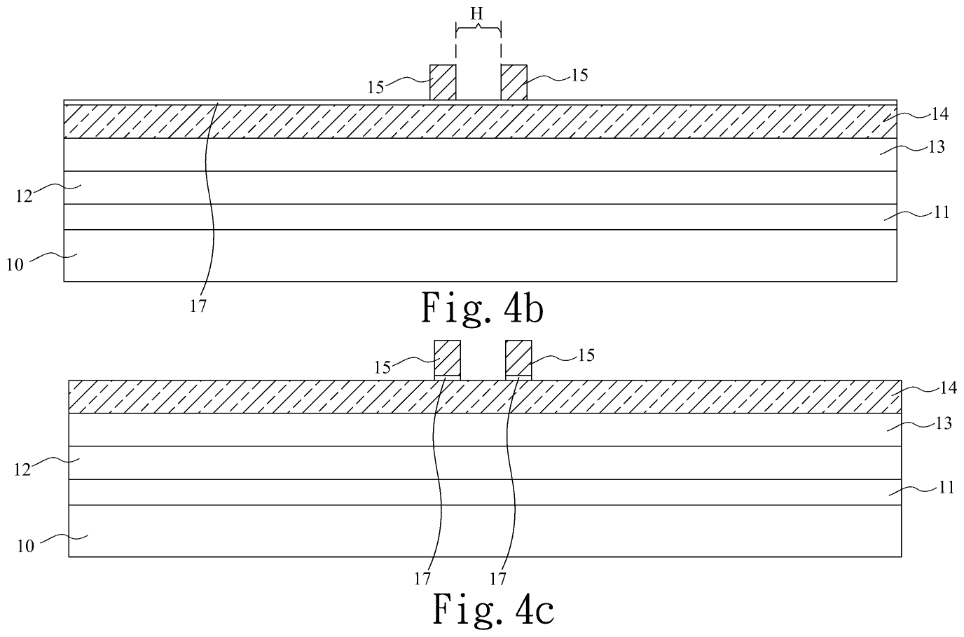

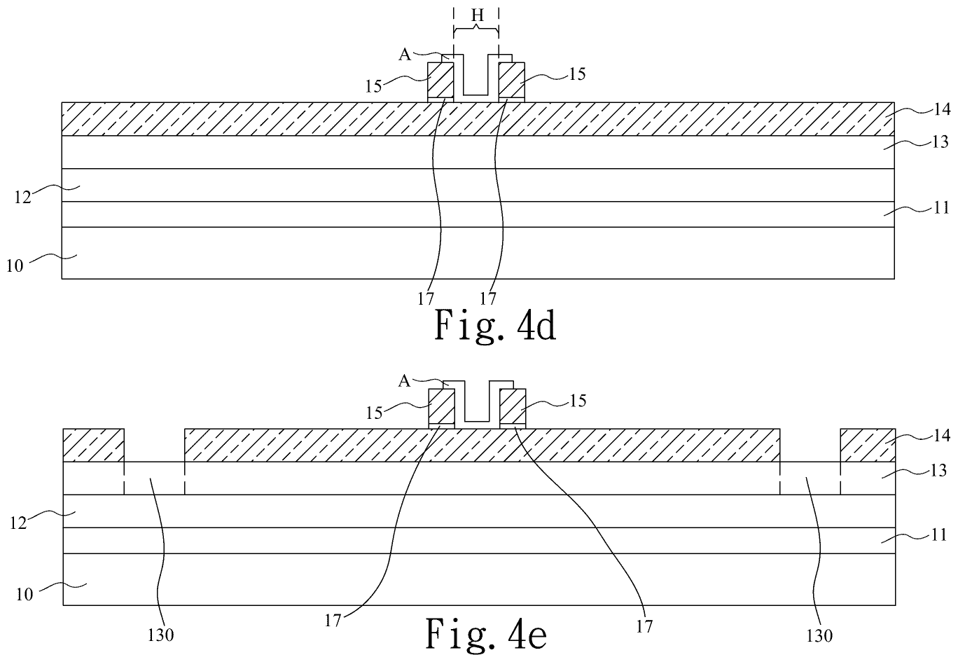

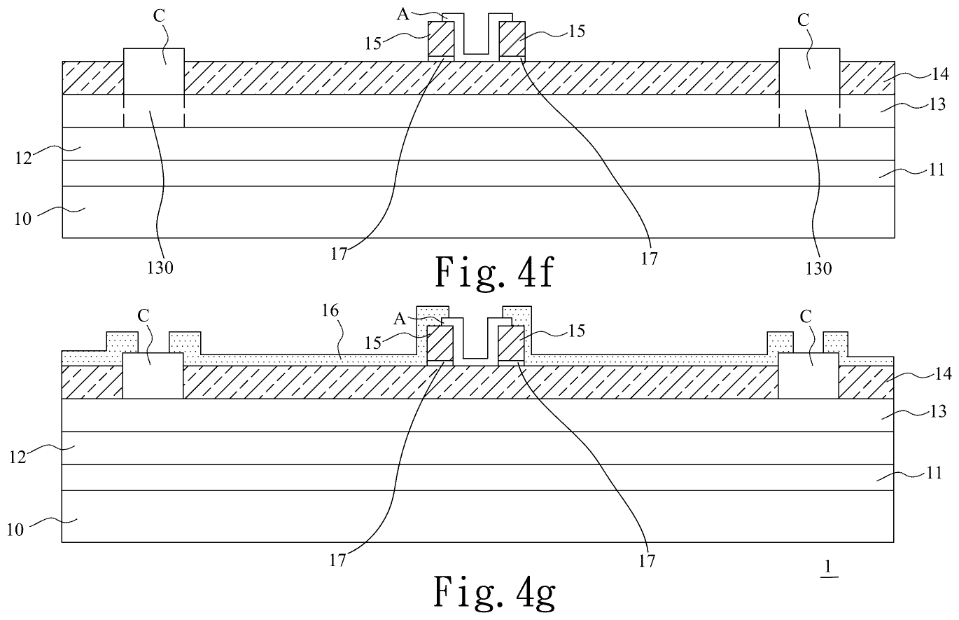

FIGS. 4a-4g are schematic diagrams illustrating the steps for fabricating a p-GaN semiconductor device according to the second embodiment of the present invention. As illustrated in FIG. 4a, a nucleation layer 11, a buffer layer 12, a GaN layer 13, an AlGaN layer 14, an etch stopping layer 17, and a p-GaN structural layer 2 are sequentially formed on a substrate 10. Then, as illustrated in FIGS. 4a-4b, a part of the p-GaN structural layer 2 is removed to form a p-GaN termination structure 15 penetrated with a hole H on the AlGaN layer 14, lest the etch stopping layer 17 exposed by the p-GaN termination structure 15 over-etch the AlGaN layer 14. As illustrated in FIG. 4c, the etch stopping layer 17 exposed by the p-GaN termination structure 15 is removed. The steps of FIGS. 4d-4g are the same to those of FIGS. 2c-2f so it will not be reiterated. Provided that substantially the same result is achieved, the steps of the flowchart shown in FIGS. 4a-4g need not be in the exact order shown and need not be contiguous, that is, other steps can be intermediate.

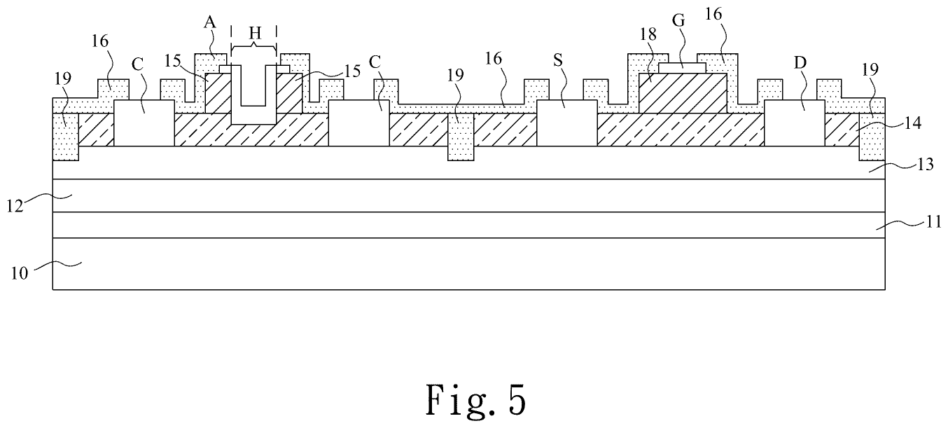

FIG. 5 is a cross-sectional view of a p-GaN semiconductor device according to a third embodiment of the present invention. Referring to FIG. 5, the third embodiment of a p-GaN semiconductor device is introduced as follows. The third embodiment is different from the first embodiment in that the third embodiment further includes a source S, a drain D, a p-GaN structure 18, a gate G, and an isolation structure 19. The source S and the drain D separate from each other, penetrate through the AlGaN layer 14, and directly interfaces the GaN layer 13. The p-GaN structure 18 is formed on the AlGaN layer 14 between the source S and the drain D. The gate G is formed on the p-GaN structure 18. The isolation structure 19 is formed in the AlGaN layer 14 and the GaN layer 13. The isolation structure 19 has a first side and a second side opposite to the first side. The cathode C is formed on the first side of the isolation structure 19 and the source S and the drain D are formed on the second side of the isolation structure 19. In some embodiments of the present invention, the isolation structure 19 may surround the cathode C, the source S, and the drain D. Besides, the insulation layer 16 covers the isolation structure 19, the p-GaN structure 18, a part of the source S, and a part of the drain D. The other structures of the third embodiment have been described in the first embodiment so it will not be reiterated.

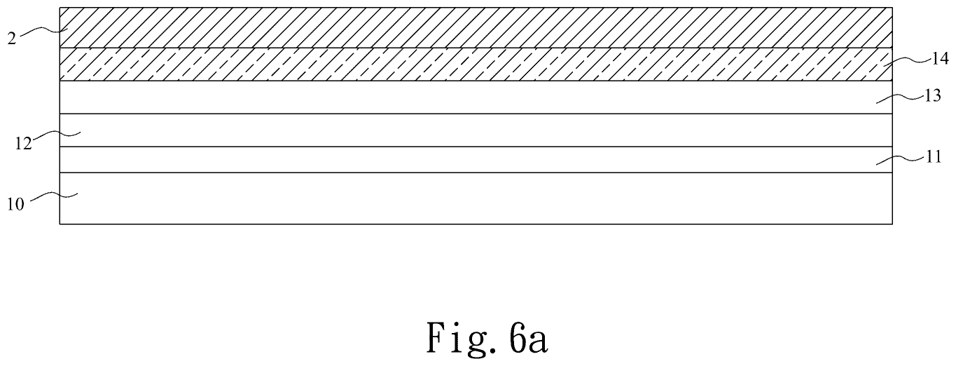

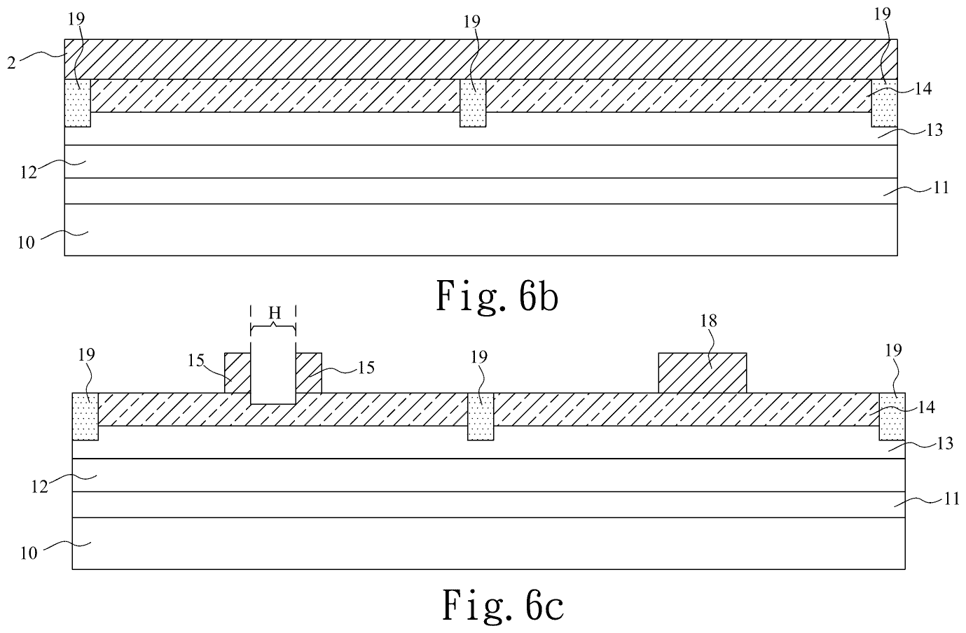

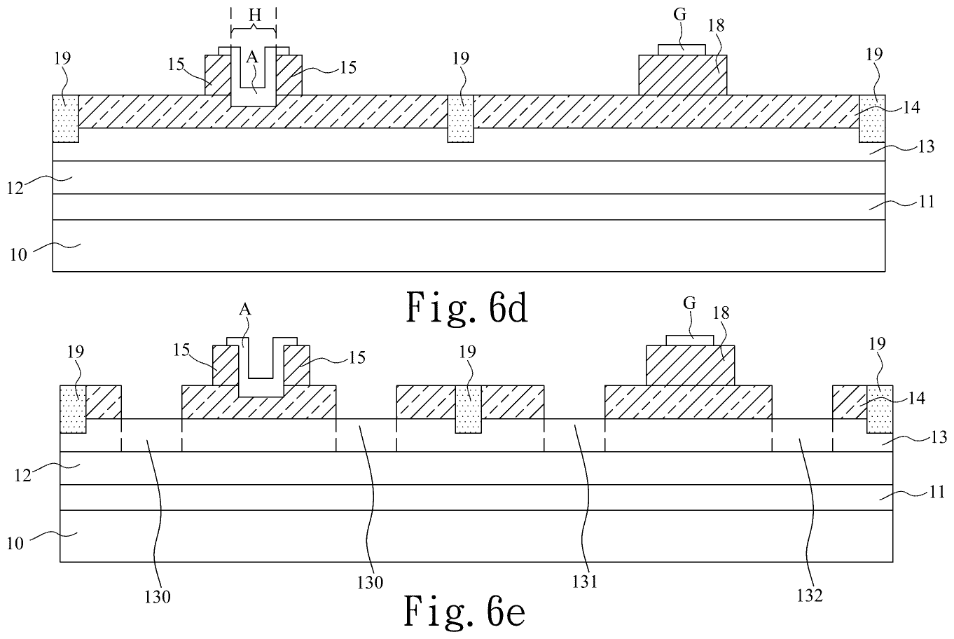

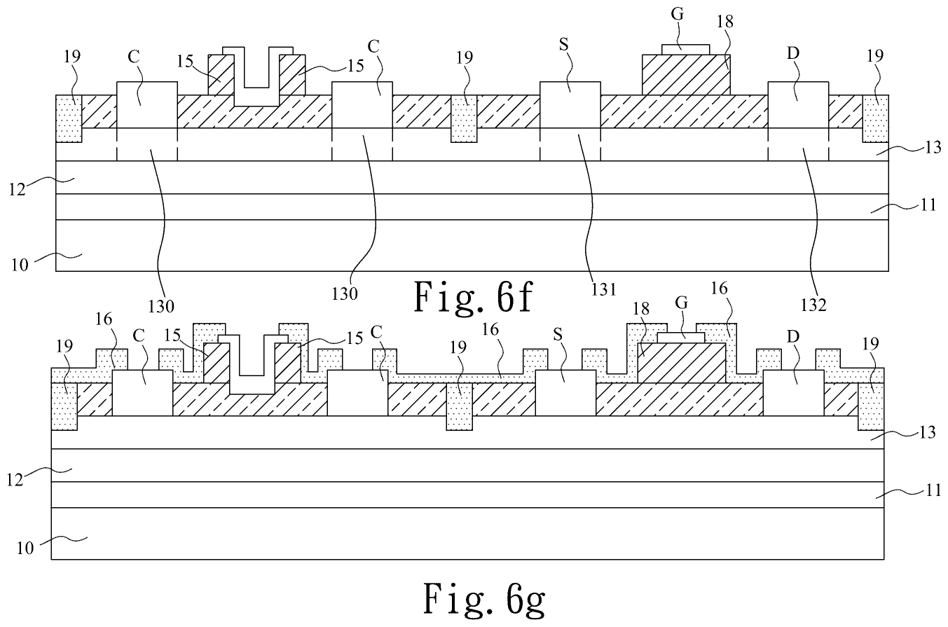

FIGS. 6a-6g are schematic diagrams illustrating the steps for fabricating a p-GaN semiconductor device according to the third embodiment of the present invention. As illustrated in FIG. 6a, a nucleation layer 11, a buffer layer 12, a GaN layer 13, an AlGaN layer 14, and a p-GaN structural layer 2 are sequentially formed on a substrate 10. Then, as illustrated in FIG. 6b, an isolation structure 19 is formed in the AlGaN layer 14 and the GaN layer 13 using ion implantation. The isolation structure 19 may include an insulating material. The isolation structure 19 has a first side and a second side opposite to the first side. In some embodiments, the isolation structure 19 may surround different areas of the AlGaN layer 14. Then, as illustrated in FIGS. 6b-6c, a part of the p-GaN structural layer 2 is removed to form a p-GaN termination structure 15 penetrated with a hole H on the AlGaN layer 14 on the first side and form a p-GaN structure 18 on the AlGaN layer 14 on the second side. As illustrated in FIG. 6d, an anode A is formed on the p-GaN termination structure 15 and the AlGaN layer 14 to fill the hole H and a gate G is formed on the p-GaN structure 18. As illustrated in FIGS. 6e-6f, a part of the AlGaN layer 14 is removed to expose at least one first block 130, a second block 131, and a third block 132 of the GaN layer 13 and at least one cathode C, a source S, and a drain D are respectively formed on the first block 130, the second block 131, and the third block 132 of the GaN layer 13. The cathode C directly interfaces the first block 130 of the GaN layer 13. In the embodiment, the number of the first blocks 130 is two and the number of the cathodes C is two. The first block 130 and the cathode C are formed on the first side of the isolation structure 19. The source S, the drain D, the second block 131, and the third block 132 are formed on the second side of the isolation structure 19. The source S and the drain D, respectively formed on two opposite sides of the AlGaN layer 14 under the p-GaN structure 18, respectively directly interface the second block 131 and the third block 132. In some embodiments, the isolation structure 19 may surround the cathode C, the source S, and the drain D. Finally, as illustrated in FIG. 6g, an insulation layer 16 may be formed to cover the isolation structure 19, the AlGaN layer 14, the p-GaN termination structure 15, the p-GaN structure 18, a part of the cathode C, a part of the anode A, a part of the source S, and a part of the drain D. Provided that substantially the same result is achieved, the steps of the flowchart shown in FIGS. 6a-6g need not be in the exact order shown and need not be contiguous, that is, other steps can be intermediate. Since the p-GaN termination structure 15 and the GaN structure 18 of the high electron mobility transistor belong to the same epitaxial material, the cost and instability of the fabrication processes can be reduced when the Schottky diode is integrated with the p-GaN transistor. The Schottky diodes and the p-GaN transistors can also be integrated into integrated circuits.

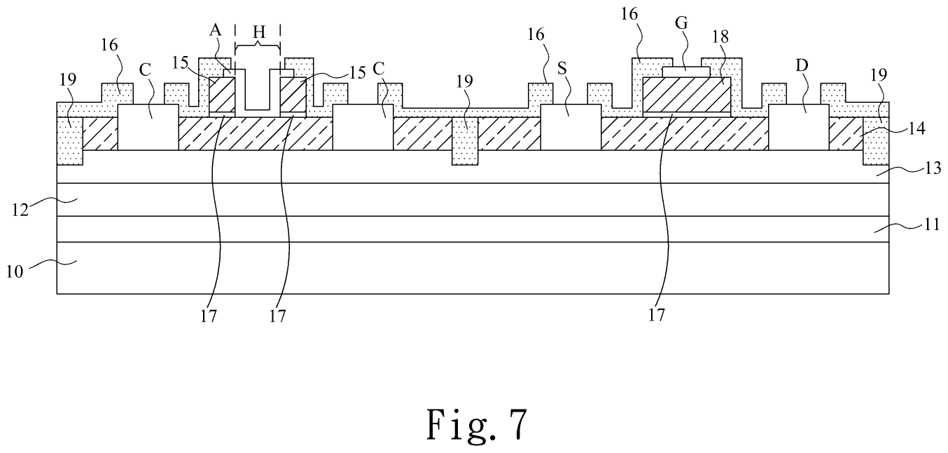

FIG. 7 is a cross-sectional view of a p-GaN semiconductor device according to a fourth embodiment of the present invention. Referring to FIG. 7, the fourth embodiment of a p-GaN semiconductor device is introduced as follows. The fourth embodiment is different from the third embodiment in that the fourth embodiment further includes an etch stopping layer 17 formed between the AlGaN layer 14 and the p-GaN termination structure 15 and formed between the AlGaN layer 14 and the p-GaN structure 18. The other structures of the fourth embodiment have been described in the third embodiment so it will not be reiterated.

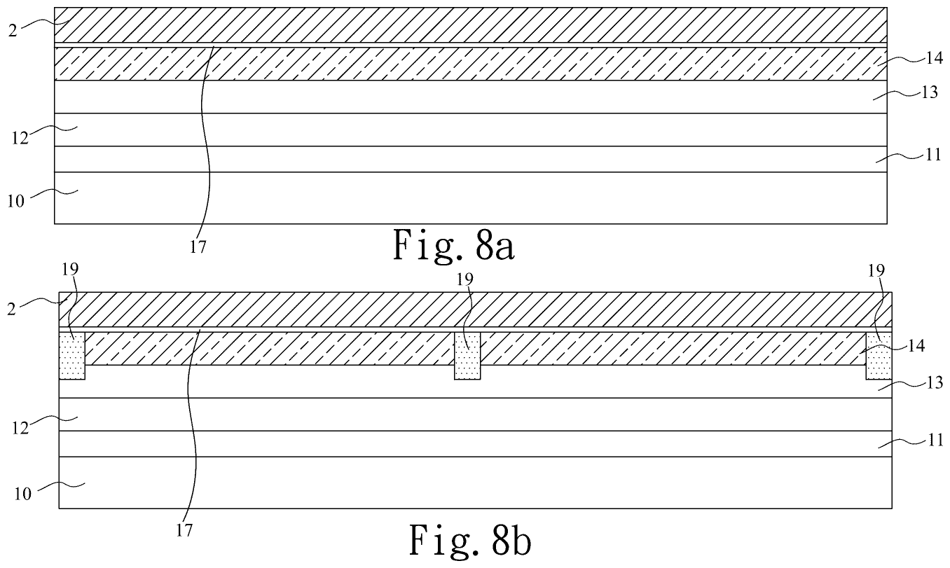

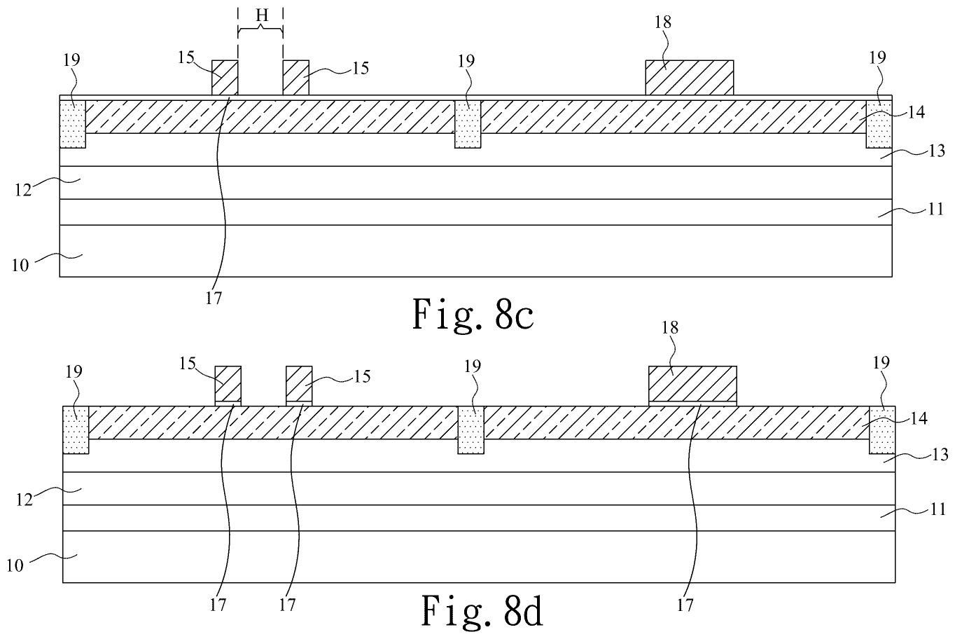

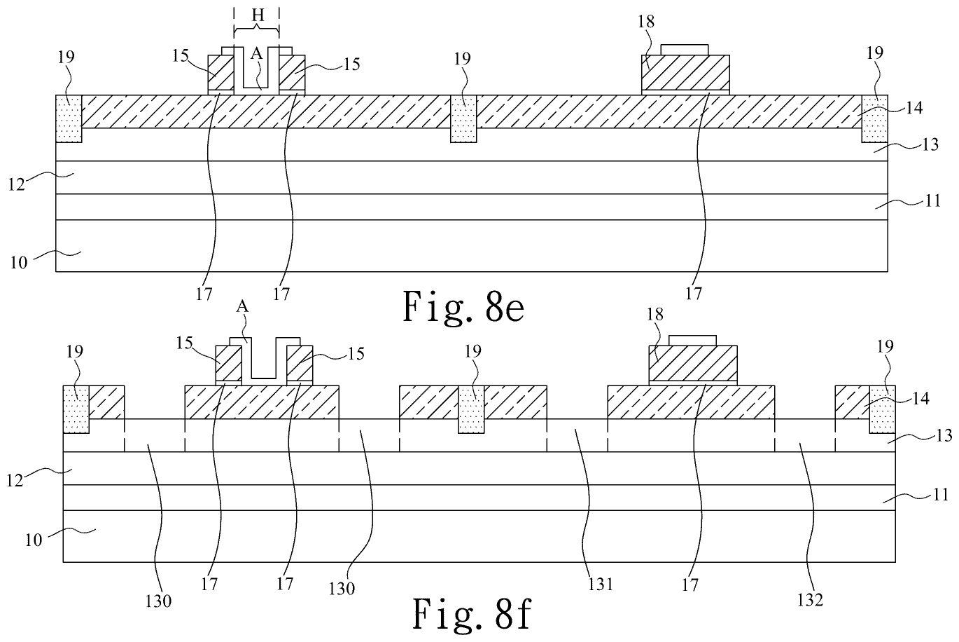

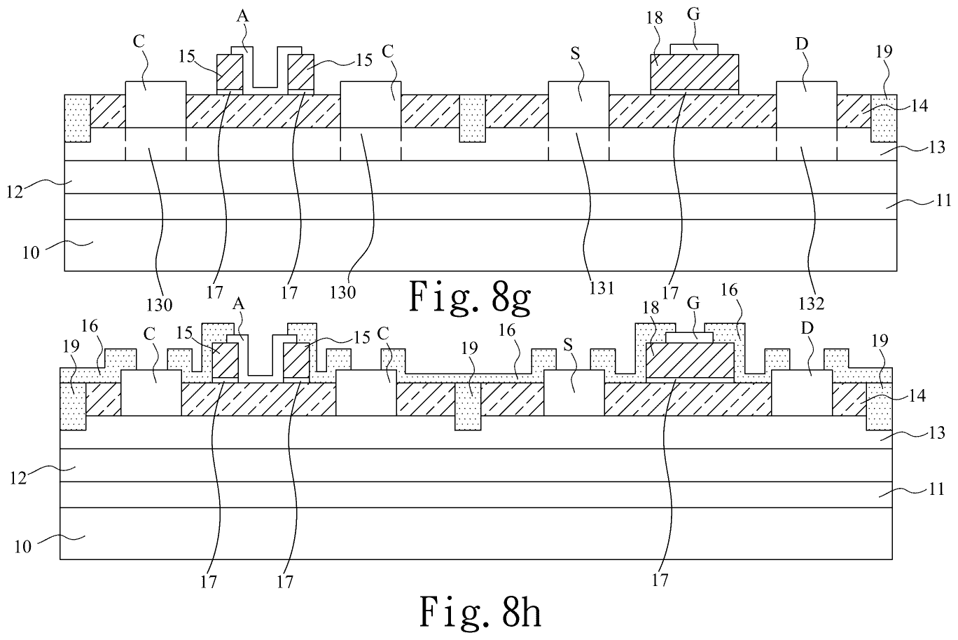

FIGS. 8a-8h are schematic diagrams illustrating the steps for fabricating a p-GaN semiconductor device according to the fourth embodiment of the present invention. As illustrated in FIG. 8a, a nucleation layer 11, a buffer layer 12, a GaN layer 13, an AlGaN layer 14, an etch stopping layer 17, and a p-GaN structural layer 2 are sequentially formed on a substrate 10. Then, as illustrated in FIG. 8b, an isolation structure 19 is formed in the AlGaN layer 14 and the GaN layer 13 using ion implantation.

The isolation structure 19 may include an insulating material. The isolation structure 19 has a first side and a second side opposite to the first side. In some embodiments, the isolation structure 19 may surround different areas of the AlGaN layer 14. Then, as illustrated in FIGS. 8b-8c, a part of the p-GaN structural layer 2 is removed to form a p-GaN termination structure 15 penetrated with a hole H on the AlGaN layer 14 on the first side and form a p-GaN structure 18 on the AlGaN layer 14 on the second side, lest the etch stopping layer 17 exposed by the p-GaN termination structure 15 and the p-GaN structure 18 over-etch the AlGaN layer 14. As illustrated in FIG. 8d, the etch stopping layer 17 exposed by the p-GaN termination structure 15 and the p-GaN structure 18 is removed. The steps of FIGS. 8e-8h are the same to those of FIGS. 6d-6g so it will not be reiterated. Provided that substantially the same result is achieved, the steps of the flowchart shown in FIGS. 8a-8h need not be in the exact order shown and need not be contiguous, that is, other steps can be intermediate.

According to the embodiments provided above, the p-GaN semiconductor device and the method for fabricating the same replace the dielectric layer with the p-GaN structural layer and etch the p-GaN structural layer under the anode to form the p-GaN termination structure of a Schottky diode, thereby providing holes and improving the stability of the diode. Since the p-GaN termination structure and the GaN structure of the high electron mobility transistor belong to the same epitaxial material, the cost and instability of the fabrication processes can be reduced when the Schottky diode is integrated with the p-GaN transistor. The Schottky diodes and the p-GaN transistors can also be integrated into integrated circuits.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A p-GaN semiconductor device comprising:
a substrate;
a nucleation layer formed on the substrate;
a buffer layer formed on the nucleation layer;
a GaN layer formed on the buffer layer;
an AlGaN layer formed on the GaN layer;
at least one cathode penetrating through the AlGaN layer and directly interfacing the GaN layer;
a p-GaN termination structure penetrated with a hole and formed on the AlGaN layer; and
an anode, formed on the p-GaN termination structure and the AlGaN layer, filling the hole.

2. The p-GaN semiconductor device according to claim 1, further comprising:
a source and a drain separating from each other, penetrating through the AlGaN layer, and directly interfacing the GaN layer;
a p-GaN structure formed on the AlGaN layer between the source and the drain; and
a gate formed on the p-GaN structure.

3. The p-GaN semiconductor device according to claim 2, further comprising an isolation structure formed in the AlGaN layer and the GaN layer, wherein the isolation structure has a first side and a second side opposite to the first side, the at least one cathode is formed on the first side of the isolation structure, and the source and the drain are formed on the second side of the isolation structure.

4. The p-GaN semiconductor device according to claim 3, wherein the isolation structure surrounds the at least one cathode, the source, and the drain.

5. The p-GaN semiconductor device according to claim 4, further comprising an insulation layer that covers the isolation structure, the AlGaN layer, the p-GaN termination structure, the p-GaN structure, a part of the at least one cathode, a part of the anode, a part of the source, and a part of the drain.

6. The p-GaN semiconductor device according to claim 2, further comprising an etch stopping layer formed between the AlGaN layer and the p-GaN termination structure and formed between the AlGaN layer and the p-GaN structure.

7. The p-GaN semiconductor device according to claim 6, wherein the etch stopping layer comprises AlN.

8. The p-GaN semiconductor device according to claim 1, wherein the buffer layer comprises GaN or AlGaN.

9. The p-GaN semiconductor device according to claim 1, wherein the nucleation layer comprises AlN.

10. The p-GaN semiconductor device according to claim 1, wherein the substrate is a Si substrate, a SiC substrate, a sapphire substrate, or a GaN substrate.

11. A method for fabricating a p-GaN semiconductor device comprising:
sequentially forming a nucleation layer, a buffer layer, a GaN layer, an AlGaN layer, and a p-GaN structural layer on a substrate;
removing a part of the p-GaN structural layer to form a p-GaN termination structure penetrated with a hole on the AlGaN layer;
forming an anode on the p-GaN termination structure and the AlGaN layer to fill the hole; and
removing a part of the AlGaN layer to expose at least one first block of the GaN layer and forming at least one cathode on the at least one first block of the GaN layer, wherein the at least one cathode directly interfaces the at least one first block of the GaN layer.

12. The method for fabricating the p-GaN semiconductor device according to claim 11, wherein after the step of forming the p-GaN structural layer, an isolation structure is formed in the AlGaN layer and the GaN layer and then the step of removing the part of the p-GaN structural layer and the part of the AlGaN layer is performed, the isolation structure has a first side and a second side opposite to the first side, and the at least one cathode and the at least one first block are formed on the first side.

13. The method for fabricating the p-GaN semiconductor device according to claim 12, wherein in the step of removing the part of the p-GaN structural layer to form the p-GaN termination structure, a part of the p-GaN structural layer is removed to form the p-GaN termination structure on the AlGaN layer on the first side and form a p-GaN structure on the AlGaN layer on the second side; in the step of removing the part of the AlGaN layer to expose the at least one first block and form the at least one cathode on the at least one first block, a part of the AlGaN layer is removed to expose the at least one first block, a second block, and a third block of the GaN layer and the at least one cathode, a source, and a drain are respectively formed on the at least one first block, the second block, and the third block, the at least one first block and the at least one cathode are formed on the first side, the source, the drain, the second block, and the third block are formed on the second side, and the source and the drain, respectively formed on two opposite sides of the AlGaN layer under the p-GaN structure, respectively directly interface the second block and the third block; and in the step of forming the anode on the p-GaN termination structure and the AlGaN layer, the anode is formed on the p-GaN termination structure and the AlGaN layer and a gate is formed on the p-GaN structure.

14. The method for fabricating the p-GaN semiconductor device according to claim 13, wherein the isolation structure surrounds the at least one cathode, the source, and the drain.

15. The method for fabricating the p-GaN semiconductor device according to claim 13, further comprising a step of forming an insulation layer to cover the isolation structure, the AlGaN layer, the p-GaN termination structure, the p-GaN structure, a part of the at least one cathode, a part of the anode, a part of the source, and a part of the drain.

16. The method for fabricating the p-GaN semiconductor device according to claim 13, wherein in the step of sequentially forming the nucleation layer, the buffer layer, the GaN layer, the AlGaN layer, and the p-GaN structural layer on the substrate, the nucleation layer, the buffer layer, the GaN layer, the AlGaN layer, an etch stopping layer, and the p-GaN structural layer are sequentially formed on the substrate; after the step of forming the p-GaN termination structure and the p-GaN structure, the etch stopping layer exposed by the p-GaN termination structure and the p-GaN structure and then the step of forming the anode and the gate and removing a part of the AlGaN layer to expose the at least one first block, the second block, and the third block is performed.

17. The method for fabricating the p-GaN semiconductor device according to claim 12, wherein the isolation structure is formed using ion implantation.
